(19) United States
(12) Patent Application Publication
(10) Pub. No.: US 2020/0245484 A1
(43) Pub. Date: Jul. 30, 2020

(54) ELECTRONIC DEVICE

(71) Applicant: FUJITSU LIMITED, Kawasaki-shi (JP)

(72) Inventors: TAKASHI KANDA, Kawasaki (JP); Shunji Baba, Yokohama (JP)

(73) Assignee: FUJITSU LIMITED, Kawasaki-shi (JP)

(21) Appl. No.: 16/703,227

(22) Filed: Dec. 4, 2019

(30) Foreign Application Priority Data
Jan. 29, 2019 (JP) 2019-013586

(51) Int. Cl. H05K 5/03

(52) U.S. Cl. CPC H05K 5/03; H02S 99/00

(57) ABSTRACT

An electronic device includes: an electronic component; a first protective member disposed so as to face one surface of the electronic component, the first protective member configured to be deformed by a shock from outside of the electronic component so as to relieve the shock; and at least one second protective member disposed so as to face a surface of the first protective member opposite the electronic component, the at least one second protective member being harder than the first protective member, the at least one second protective member having a rod shape.

### CROSS-REFERENCE TO RELATED APPLICATION

This application is based upon and claims the benefit of priority of the prior Japanese Patent Application No. 2019-13586, filed on Jan. 29, 2019, the entire contents of which are incorporated herein by reference.

### FIELD

The embodiments discussed herein are related to an electronic device.

### BACKGROUND

There is a wireless integrated circuit (IC) tag that includes an IC chip, an antenna member, and a protective material that protects the IC chip and the antenna member.

There also is an IC card that includes an IC module, an intermediate adhesive layer, and an outer surface laminate layer. The IC module is interposed between the intermediate adhesive layer and the outer surface laminate layer.

Japanese Laid-open Patent Publication Nos. 2007-4323 and 2005-234683 are examples of related art.

### SUMMARY

According to an aspect of the embodiments, an electronic device includes: an electronic component; a first protective member disposed so as to face one surface of the electronic component, the first protective member configured to be deformed by a shock from outside of the electronic component so as to relieve the shock; and at least one second protective member disposed so as to face a surface of the first protective member opposite the electronic component, the at least one second protective member being harder than the first protective member, the at least one second protective member having a rod shape.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is an exploded perspective view illustrating an electronic device according to a first embodiment;

FIG. 2 is a perspective view illustrating the electronic device according to the first embodiment;

FIG. 3 is a side view illustrating the electronic device according to the first embodiment on which no load acts from outside;

FIG. 4 is a plan view illustrating the electronic device according to the first embodiment;

FIG. 5 is a front view illustrating the electronic device according to the first embodiment in a flat state;

FIG. 6 is a front view illustrating the electronic device according to the first embodiment in a curved state;

FIG. 7 is a front view illustrating the electronic device according to the first embodiment curved in an opposite direction to that of FIG. 6;

FIG. 8 is a side view illustrating the electronic device according to the first embodiment on which a load acts from outside;

FIG. 9 is a perspective view illustrating the electronic device according to the first embodiment mounted on a mounting target;

FIG. 10 is a perspective view illustrating the electronic device according to the first embodiment mounted on a mounting target different from the mounting target illustrated in FIG. 9;

FIG. 11 is a front view illustrating the electronic device according to the first embodiment mounted on a mounting target different from the mounting target illustrated in FIG. 9 or 10;

FIG. 12 is a side view illustrating an electronic device according to a second embodiment on which no load acts from outside;

FIG. 13 is a side view illustrating the electronic device according to the second embodiment on which a load acts from outside;

FIG. 14 is a side view illustrating an electronic device according to a third embodiment on which no load acts from outside;

FIG. 15 is a side view illustrating the electronic device according to the third embodiment on which a load acts from outside; and

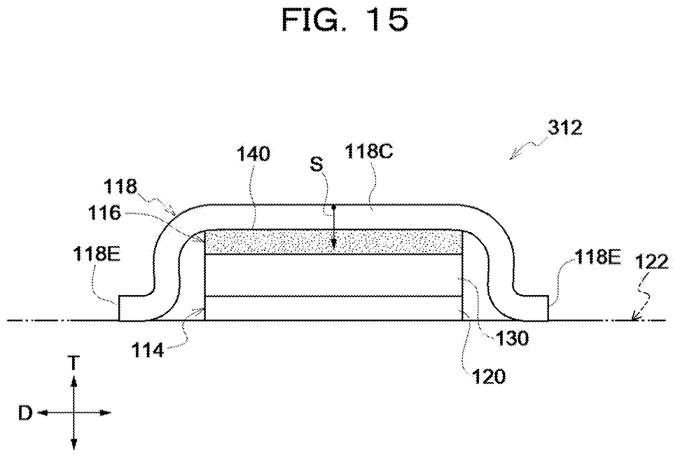

FIG. 16 is a plan view illustrating an electronic device according to a variant.

### DESCRIPTION OF EMBODIMENTS

When an electronic component such as an IC chip or an IC module in a curved state is able to be mounted on a mounting target, the electronic component is able to be mounted on a curved surface, and accordingly, able to be mounted on various types of mounting targets. It is also desired that the electronic component be protected from shocks from outside.

For protecting the electronic component from the shocks, for example, a protective member may be bonded to the electronic component. However, when a hard protective member is bonded to the electronic component, the curving property (ease of curving) of the electronic component is degraded. When a soft protective member is bonded to the electronic component, it is difficult to relieve the shocks so as to reliably protect the electronic component.

As an aspect, degradation of a curving property of an electronic component may be suppressed, and, in addition, shocks from outside may be relieved so as to protect the electronic component.

An electronic device 112 according to a first embodiment is described in detail with reference to the drawings.

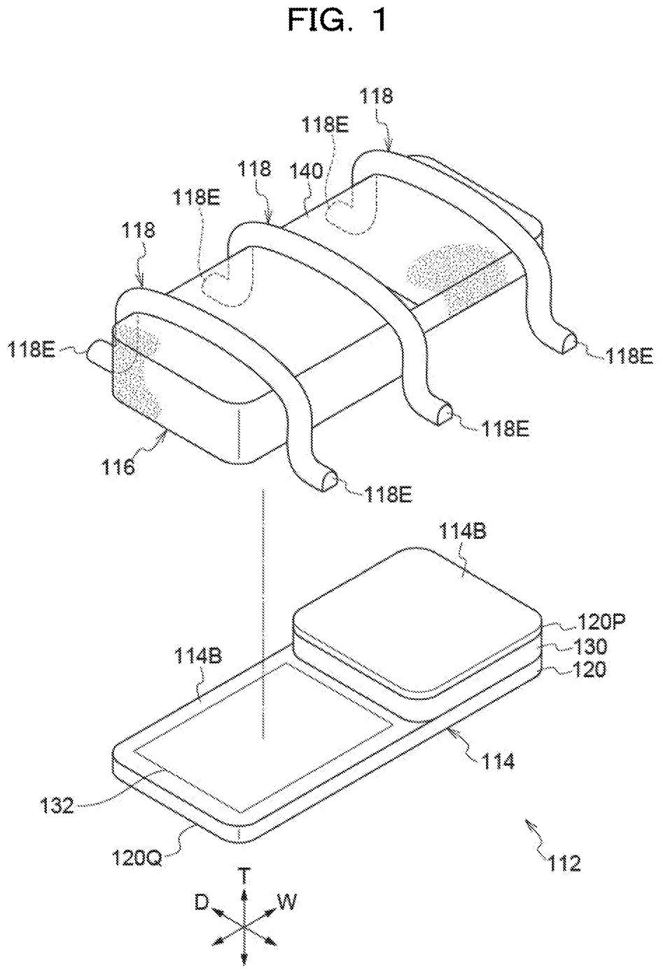

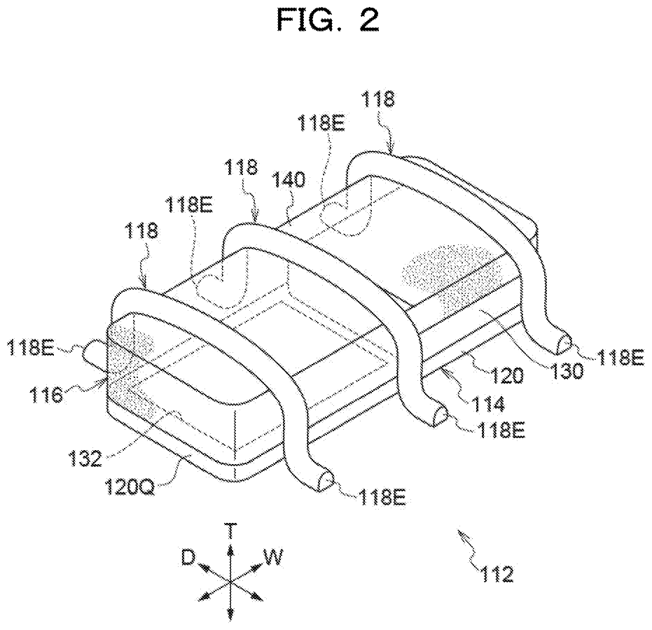

As illustrated in FIGS. 1 and 2, the electronic device 112 includes an electronic component 114, a first protective member 116, and second protective members 118.

The electronic component 114 includes a base plate 120. The base plate 120 is formed of rubber, soft resin (for example, silicone rubber), or the like such that the base plate 120 is able to be curved. The base plate 120 is a plate-shaped member having a rectangular shape (flat rectangular parallelepiped shape) in plan view. The plate shape refers to a shape in which the thickness is sufficiently thin compared to the width and the depth and which is substantially sufficiently bent (curved) in the thickness direction. In the drawings, the width direction, the depth direction, and the thickness direction of the electronic component 114 (base plate 120) are indicated by arrows W, D, and T, respectively. The electronic component 114 (base plate 120) has a rectangular shape in plan view. The longitudinal direction of the electronic component 114 is coincident with the width direction, and the lateral direction of the electronic component 114 is coincident with the depth direction. Furthermore, the width direction, the depth direction and the thickness direction of the electronic component 114 are coincident with the width direction, the depth direction and the thickness direction of the first protective member 116, respectively.

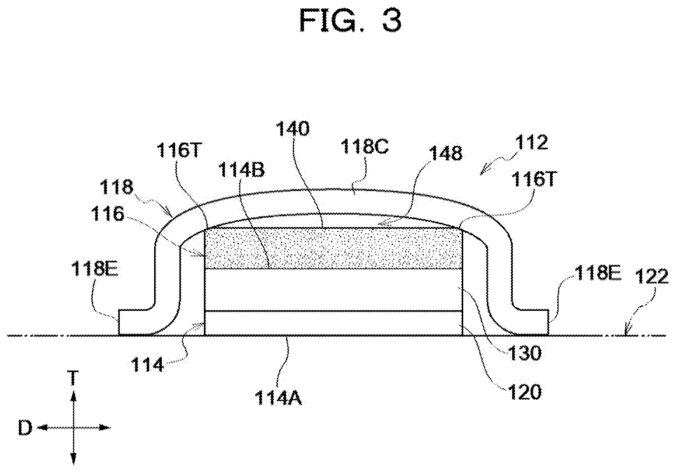

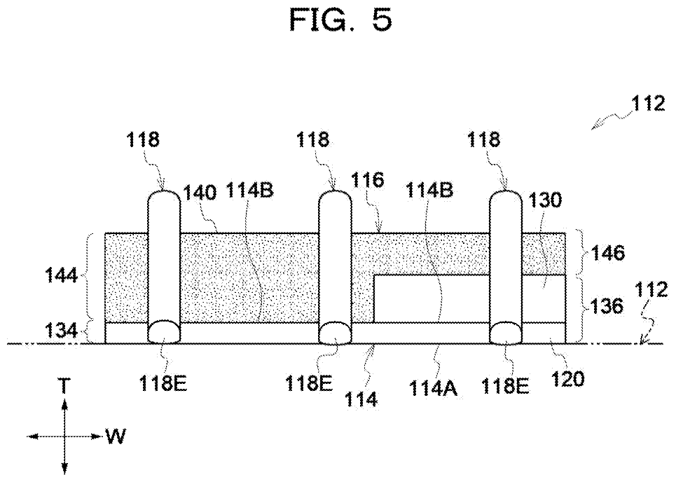

One surface of the base plate 120 is a mounting surface 114A of the electronic component 114. As illustrated in FIGS. 3 and 5, the electronic device 112 is mounted on a mounting target 122 with the mounting surface 114A in contact with the mounting target 122.

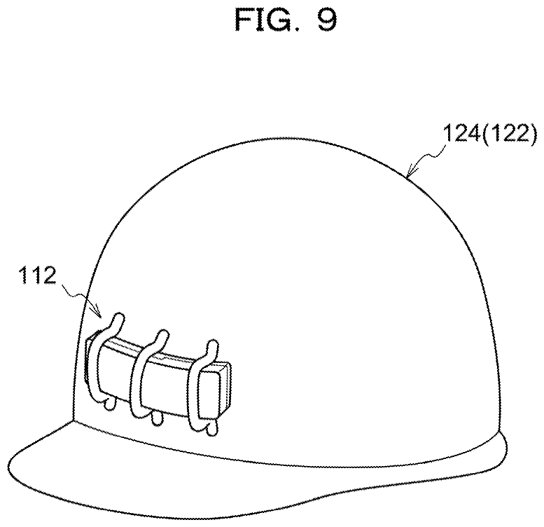

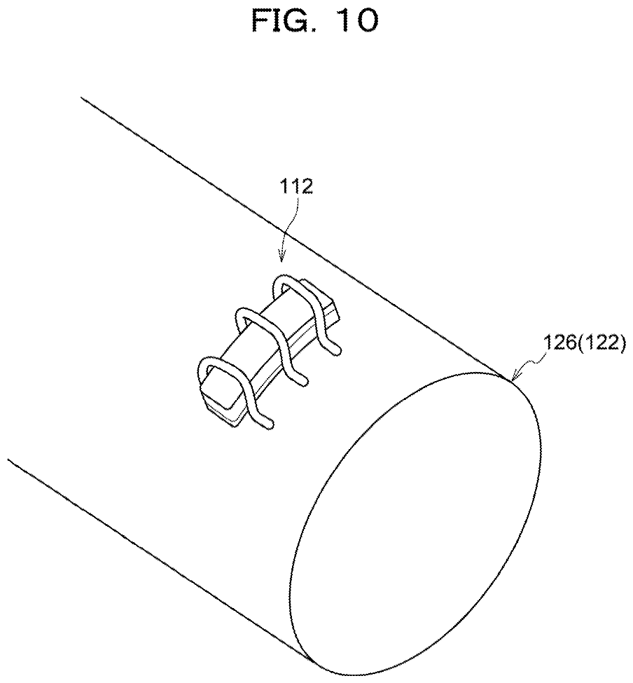

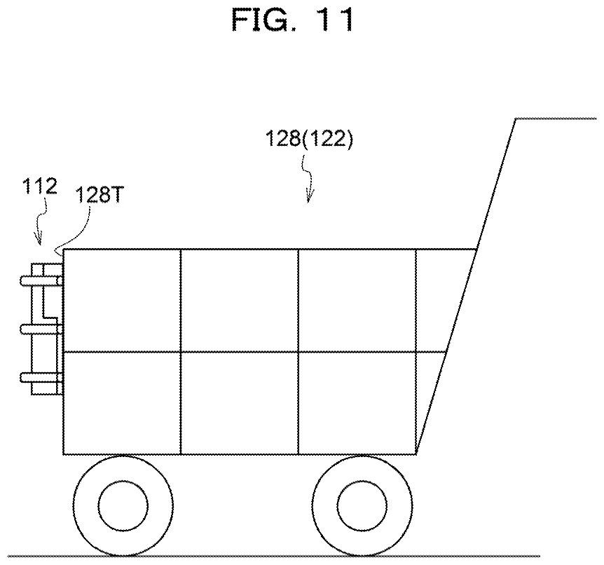

Examples of the mounting target 122 include, for example, a protective hat 124 illustrated in FIG. 9, a prismatic member (columnar member) 126 illustrated in FIG. 10, and a cart 128 illustrated in FIG. 11. Since the base plate 120 is able to be curved, the electronic device 112 may be mounted on, for example, a curved portion such as a protective hat 124 or a columnar member 126. Since the base plate 120 has a planar shape, the electronic device 112 may be mounted on a flat portion (such as a mounting surface 128T of the cart 128).

The electronic component 114 includes an electronic component main body 130 fixed to the side of the base plate 120 opposite the mounting surface 114A. The electronic component main body 130 according to the present embodiment includes, for example, an electronic circuit, a processor, a memory, an antenna, and the like. Thus, the electronic component main body 130 is able to send and receive radio waves to and from outside.

The electronic component main body 130, which has a thickness larger than that of the base plate 120, is sufficiently flexible to be curved together with the base plate 120.

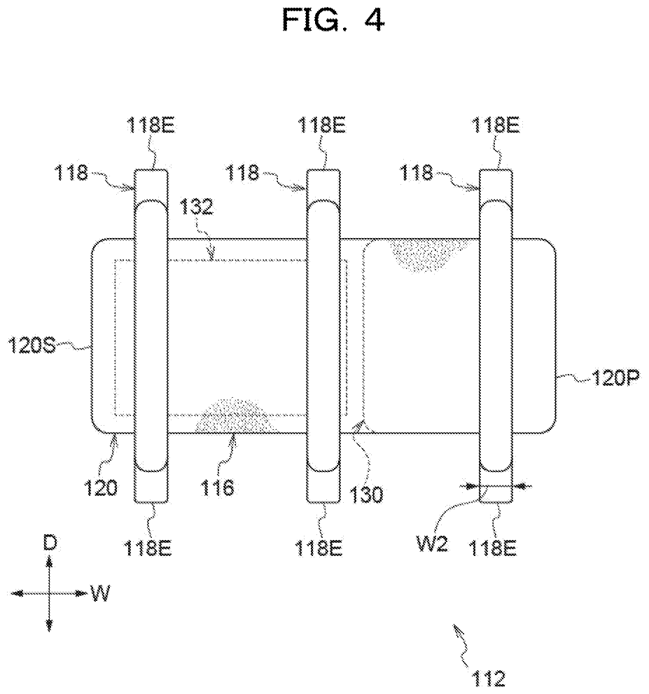

As illustrated in FIG. 4, the electronic component main body 130 is fixed to a one end 120P side of the base plate 120 in the width direction (the arrow W direction) in plan view of the electronic component 114. According to the present embodiment, a solar cell panel 132 is provided in a portion of the base plate 120 where the electronic component main body 130 is not fixed (a portion on another end 120Q side). When the solar cell panel 132 is irradiated with light, power is generated. The generated power is supplied to the electronic component main body 130.

As illustrated in FIGS. 1 and 5, when the entirety of the electronic component 114 is seen, the portion of the base plate 120 where the electronic component main body 130 is not fixed is a thin plate portion 134 having a relatively small thickness. In contrast, a portion where the electronic component main body 130 is fixed is a thick plate portion 136 having a relatively large thickness.

In a state in which the electronic component 114 is mounted on the mounting target 122, surfaces of the thin plate portion 134 and the thick plate portion 136 opposite the mounting surface 114A are protected surfaces 114B to be protected from shocks from outside.

As illustrated in FIGS. 1 to 3, the first protective member 116 is disposed so as to face the protected surfaces 114B.

The first protective member 116 is a plate-shaped member formed of a soft material, a rubber, a soft resin, or the like (for example, silicone rubber). According to the present embodiment, a surface of the first protective member 116 opposite the electronic component 114 is an exposed surface 140 exposed to the outside of the electronic device 112.

According to the present embodiment, the electronic component 114 includes the thin plate portion 134 and the thick plate portion 136. The first protective member 116 includes a thick portion 144 corresponding to the thin plate portion 134 and a thin portion 146 corresponding to the thick plate portion 136. The first protective member 116 including the thick portion 144 and the thin portion 146 as described above is in surface contact with the protected surfaces 114B of the thin plate portion 134 and the thick plate portion 136. In a state in which the first protective member 116 is mounted on the electronic component 114, the exposed surface 140 of the first protective member 116 (the surface opposite the electronic component 114) is flat.

As illustrated in FIG. 4, the first protective member 116 has a shape coincident with the electronic component 114 (base plate 120) in plan view.

The first protective member 116 according to the present embodiment is transparent. Accordingly, even when the solar cell panel 132 is covered with the first protective member 116, light reaches the solar cell panel 132 from outside. The first protective member 116 is regarded as “transparent” as long as the first protective member 116 has a degree of optical transparency as described above with which the solar cell panel 132 is able to generate power.

As illustrated in FIGS. 2 and 3, the second protective members 118 are disposed outside the exposed surface 140 of the first protective member 116. The second protective members 118 having a rod shape are formed of a material harder than that of the first protective member 116, metal, hard resin (for example, acrylic resin), or the like. The second protective members 118 having a rod shape are disposed so as to straddle the electronic component 114.

In the example according to the present embodiment, a plurality of (three in the example illustrated in FIGS. 2, 4, and 5) second protective members 118 are provided. However, the number of second protective members 118 is not limited and may be one, two, or four or more. The plurality of second protective members 118 may be formed of the same material or different materials.

As illustrated in FIG. 4, the three second protective members 118 are each disposed such that, in plan view of the electronic component 114, the longitudinal direction of the second protective member 118 is parallel to the lateral direction of the electronic component 114 (arrow D direction). End portions 118E of the second protective member 118 in the longitudinal direction project from the electronic component 114 (base plate 120) in plan view.

As illustrated in FIGS. 3 and 5, the end portions 118E of the second protective member 118 extend from a central portion 118C in the longitudinal direction toward the mounting surface 114A (lower side in FIG. 3) and further extend in the depth direction. According to the present embodiment, the end portions 118E of the second protective member 118 are in contact with the mounting target 122. The end portions 118E may be fixed to the mounting target 122 by, for example, bonding or simply in contact with the mounting target 122 without being fixed.

According to the present embodiment, as illustrated in FIG. 3, the central portion 118C of the second protective member 118 is curved convexly in a direction opposite the electronic component 114 (upward in FIG. 3). Since the second protective member 118 is curved in this manner, a gap 148 is formed between the first protective member 116 and the second protective member 118. However, at end portions 116T of the first protective member 116 in the lateral direction, the second protective member 118 is in contact with the first protective member 116.

As illustrated in FIGS. 4 and 5, the three second protective members 118 are equally spaced from one another in the longitudinal direction of the electronic component 114 (arrow W direction). For example, in the longitudinal direction of the electronic component 114, one of the second protective members 118 is disposed at the center, another of the second protective members 118 is disposed on the one end 120P side, and yet another of the second protective members 118 is disposed on the other end 120Q side.

Although the three second protective members 118 are equally spaced in the example illustrated in FIGS. 4 and 5, the spaces between the second protective members 118 are not necessarily equal.

To obtain the actual electronic device 112, for example, as illustrated in FIG. 1, a structure in which the second protective members 118 are disposed at the first protective member 116 and integrated with the first protective member 116 is produced, and the first protective member 116 of this structure is affixed to the electronic component 114.

Next, operations according to the present embodiment are described.

The electronic device 112 according to the present embodiment includes the base plate 120 and the first protective member 116. The base plate 120 and the first protective member 116 are formed of rubber, soft resin, or the like such that the base plate 120 and the first protective member 116 are able to be curved. Accordingly, the electronic component 114 and the first protective member 116 allow curving of the electronic device 112 without causing large resistance to act when the electronic device 112 is curved.

The electronic device 112 also includes the second protective members 118. The second protective members 118 have the rod shape the longitudinal direction of which extends perpendicular to the longitudinal direction of the electronic device 112. Thus, when the electronic device 112 is curved along the longitudinal direction, the second protective members 118 do not cause resistance to act on the curving. Accordingly, the electronic device 112 is able to be curved.

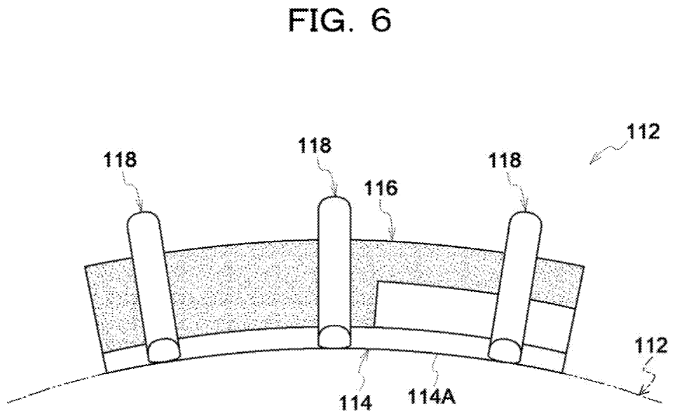

For example, in the example illustrated in FIG. 6, the electronic device 112 is curved with the mounting surface 114A side being concave. In this case, the spaces between the second protective members 118 increase, and resistance to the curving of the electronic device 112 does not act.

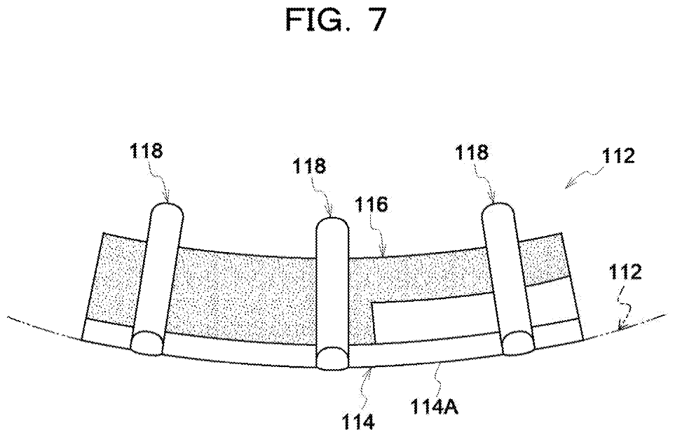

In contrast, in the example illustrated in FIG. 7, the electronic device 112 is curved with the mounting surface 114A side being convex. In this case, the spaces between the second protective members 118 reduce, and resistance to the curving of the electronic device 112 does not act.

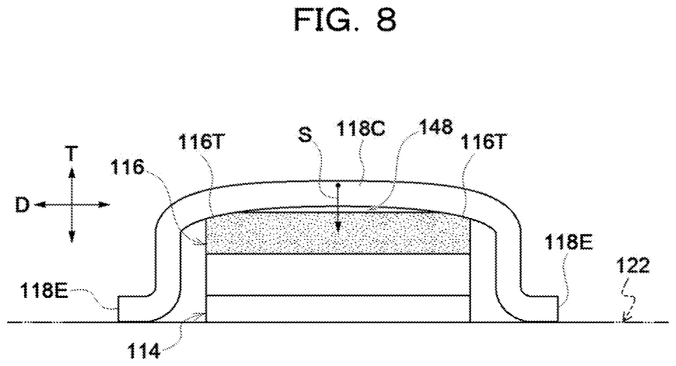

The electronic device 112 according to the present embodiment includes the first protective member 116 and the second protective members 118. This may relieve shocks from outside. As illustrated in FIG. 8, when the shock S acts on the second protective members 118, this second protective member 118 is bent so as to reduce the gaps 148 between the first protective member 116 and the second protective members 118. This may absorb the shock.

Portions of the second protective members 118 in contact with the first protective member 116 push parts of the first protective member 116 (the end portions 116T and regions near the end portions 116T), thereby locally compressing the first protective member 116. This compression of the first protective member 116 may also absorb the shock S.

As has been described, the electronic device 112 according to the present embodiment, which includes the first protective member 116 and the second protective members 118, may suppress degradation of the curving property (ease of curving), and relieve shocks from outside so as to protect the electronic component 114.

Next, a second embodiment is described. For the second embodiment, elements, members, and so forth similar to those of the first embodiment are denoted by the same reference signs as those of the first embodiment, thereby omitting the detailed description thereof.

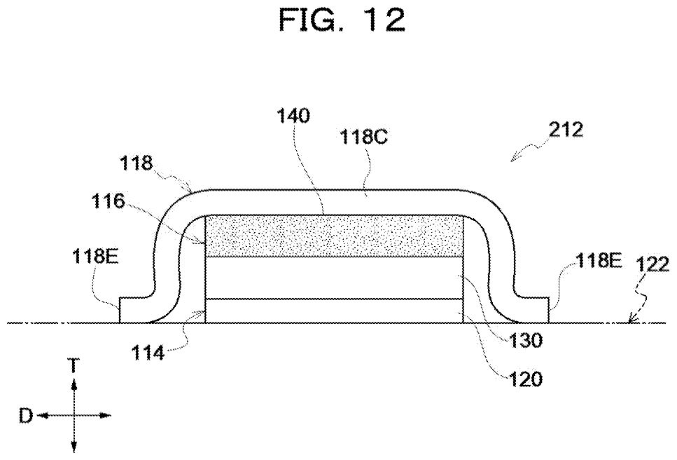

As illustrated in FIG. 12, in an electronic device 212 according to the second embodiment, the central portion 118C of each of the second protective members 118 is linear when the central portion 118C is not subjected to shocks. The central portion 118C is in line contact with the first protective member 116. For example, there is no gap between the first protective member 116 and the second protective member 118.

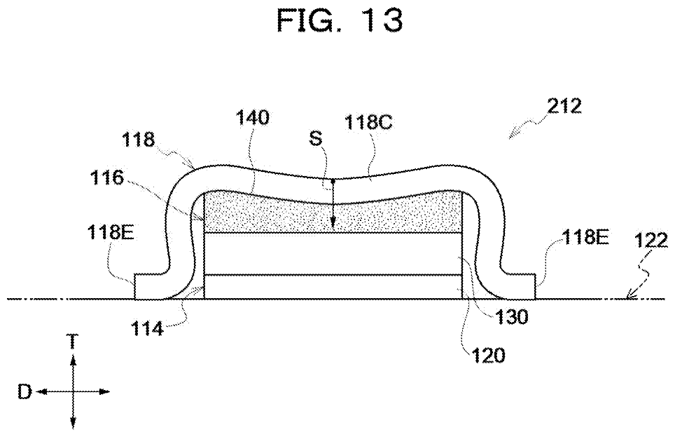

Thus, in the electronic device 212 according to the second embodiment, as illustrated in FIG. 13, when the second protective member 118 is bent by the shock S acting from outside, the first protective member 116 is pushed in a range in which the second protective member 118 is in line contact with the first protective member 116. This causes the second protective member 118 to compress the first protective member 116 along a line. For example, also according to the second embodiment, the first protective member 116 and the second protective member 118 may relieve the shock S from outside so as to protect the electronic device 112.

The second protective member 118 may be fixed to the first protective member 116 by bonding or the like or simply in contact with the first protective member 116 without being fixed.

When the second protective member 118 is fixed to the first protective member 116, the position of the second protective member 118 relative to the first protective member 116 may be stably maintained. In this case, the end portions 118E of the second protective member 118 may be fixed to the mounting target 122 or is not necessarily fixed to the mounting target 122.

In contrast, when the second protective member 118 is not fixed to the first protective member 116, the second protective member 118 is allowed to move relative to the first protective member 116. Thus, the resistance to the curving of the electronic device 112 is reduced. In this structure, the end portions 118E of the second protective member 118 are fixed to the mounting target 122.

According to both the first embodiment and the second embodiment, the second protective member 118 is in contact with the mounting target 122 at the end portions 118E. Thus, when the second protective member 118 is bent by shocks, both end portions 118E are supported by the mounting target 122. This may cause the central portion 118C to be reliably bent.

Next, a third embodiment is described. Also for the third embodiment, elements, members, and so forth similar to those of the first embodiment are denoted by the same reference signs as those of the first embodiment, thereby omitting the detailed description thereof.

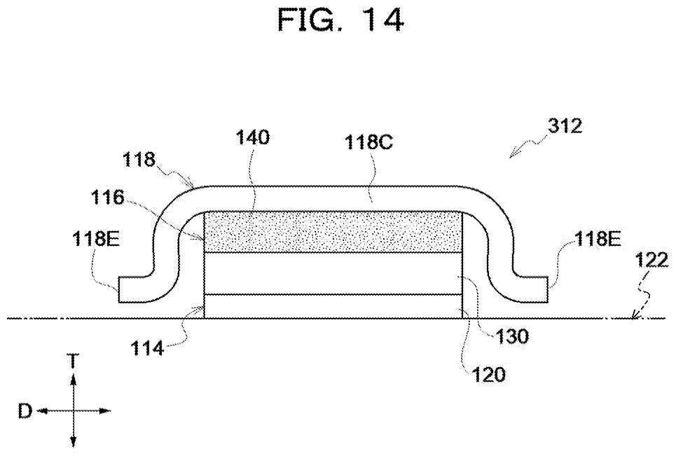

As illustrated in FIG. 14, in an electronic device 312 according to the third embodiment, similarly to the electronic device 212 according to the second embodiment, the central portion 118C of each of the second protective members 118 is linear when the central portion 118C is not subjected to shocks. For example, the central portion 118C is in line contact with the first protective member 116, and there is no gap between the first protective member 116 and the second protective member 118.

However, unlike the second protective member 118 according to the second embodiment, the end portions 118E of the second protective member 118 are spaced from the mounting target 122 in the electronic device 312 according to the third embodiment.

Thus, in the electronic device 312 according to the third embodiment, when shocks act on the second protective member 118 from outside, the second protective member 118, while approaching the mounting target 122, pushes the first protective member 116 so as to compress the first protective member 116 in a range in which the second protective member 118 is in line contact with the first protective member 116. Accordingly, the shocks from outside may be relieved so as to protect the electronic device 112.

Next, a variant is described. Also for the variant, elements, members, and so forth similar to those of the first embodiment are denoted by the same reference signs as those of the first embodiment, thereby omitting the detailed description thereof.

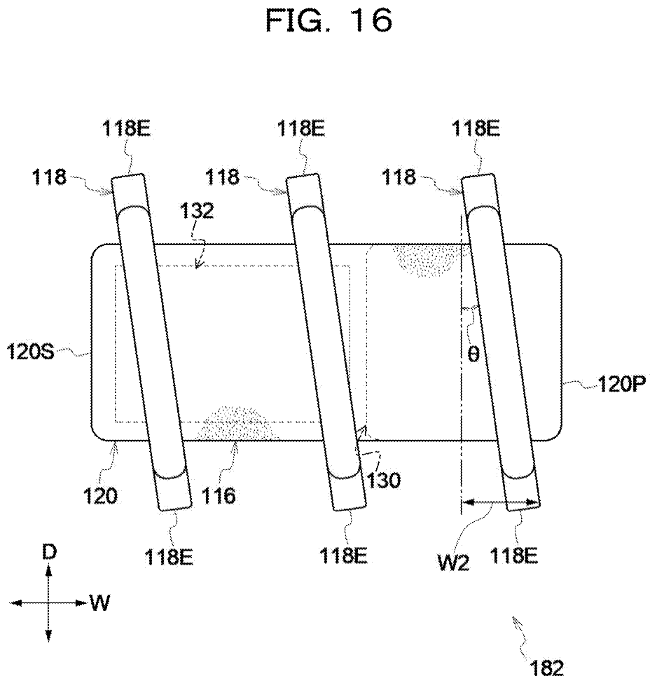

As illustrated in FIG. 16, Although an electronic device 182 according to the variant includes the second protective members 118 similar to those of the first embodiment, the longitudinal direction of the second protective members 118 is, in plan view, inclined relative to the lateral direction of the electronic component 114 (arrow D direction) by a predetermined inclination angle θ.

The second protective members 118 may be disposed so as to be inclined relative to the electronic component 114 in plan view as described above. However, each of the second protective member 118 substantially occupies a predetermined range having a width of W2 in plan view. Thus, as the inclination angle θ of the second protective members 118 approaches 90 degrees, the resistance to the curving of the electronic device 112 increases. In contrast, as is the case with the example illustrated in FIG. 4, when the longitudinal direction of the second protective member 118 is coincident with the lateral direction (direction perpendicular to the longitudinal direction) of the electronic component 114 in plan view of the electronic device 112, the width W2 occupied by the second protective member 118 is small. In the example illustrated in FIG. 4, the width W2 is substantially the width of the second protective member 118 without being influenced by the inclination of the second protective member 118. Thus, when the electronic device 112 is curved along the longitudinal direction, a portion where the second protective member 118 becomes the resistance is substantially reduced.

In the electronic device 182 according to the variant, the shape and structure of the second protective member 118 may be, for example, those of the second embodiment or the third embodiment.

According to the embodiments and the variant, the first protective member 116 has a plate shape. Although the first protective member 116 may have a block shape instead of a plate shape, the plate-shaped first protective member 116 may protect the electronic component 114 from shocks by covering the protected surfaces 114B of the electronic component 114 without increasing the thickness. Even when the plate-shaped first protective member 116 is locally slit or recessed, as long as the first protective member 116 generally has a plate shape, the protected surfaces 114B of the electronic component 114 may be covered by the first protective member 116 without increasing the thickness.

The electronic component 114 has the mounting surface 114A. With the mounting surface 114A, the electronic component 114 is able to be mounted on the mounting target 122 while being in surface contact with the mounting target 122. When the electronic component 114 is mounted on the mounting target 122 at the mounting surface 114A as described above, shocks due to external force are likely to act on the surface opposite the mounting surface 114A. According to the above-described embodiments, the first protective member 116 is disposed so as to face the protected surfaces 114B opposite the mounting surface 114A. Thus, the protected surfaces 114B may be reliably protected from the shocks.

The first protective member 116 is not necessarily in contact with the protected surfaces 114B. The first protective member 116 may face the protected surfaces 1148 with gaps interposed therebetween. In the structure in which the first protective member 116 is in contact with the protected surfaces 114B, the thickness of the entire electronic device 112 may be reduced compared to a structure in which the gaps are interposed between the first protective member 116 and the protected surfaces 114B.

According to the embodiments and the variant, the first protective member 116 is in surface contact with the protected surfaces 114B of the electronic component 114. Since the contact area is larger than a structure in which the first protective member 116 is in point contact with or line contact with the protected surfaces 114B, local load (pressure) from the first protective member 116 to the electronic component 114 may be relieved. Furthermore, the position of the first protective member 116 relative to the electronic component 114 may be stably maintained.

Furthermore, the first protective member 116, the shape of which is coincident with the shape of the electronic component 114 (base plate 120) in plan view, covers the entirety of the protected surfaces 114B. Consequently, the entirety of the protected surfaces 114B may be protected from shocks. When the first protective member 116 covers the entirety of the protected surfaces 114B as described above, for example, there may be a portion that projects outward from the electronic component 114 in plan view. When the shape of the first protective member 116 is coincident with the shape of the electronic component 114 (base plate 120) in plan view as is the case with the embodiments herein, a structure in which the entirety of the protected surfaces 114B is covered is able to be realized without increasing the size of the first protective member 116.

In the electronic device 112 according to the embodiments, the electronic component 114 includes the thin plate portion 134 and the thick plate portion 136. Correspondingly, the first protective member 116 includes the thick portion 144 and the thin portion 146. Thus, a structure in which the first protective member 116 is in contact with the protected surfaces 114B of the thin plate portion 134 and the thick plate portion 136 of the electronic component 114 is able to be realized.

According to the embodiments and the variant, the first protective member 116 is transparent. When the electronic component 114 includes, for example, the solar cell panel 132, the power may be reliably generated by making the solar cell panel 132 irradiated with light. The “transparent” member is not limited to a member transmitting visible light and may also mean a member transmitting infrared light or ultraviolet light. For example, in a structure that includes, instead of the solar cell panel 132, a sending/receiving unit for sending and receiving, for example, infrared light or ultraviolet light, it is sufficient that infrared light or ultraviolet light be transmitted to such a degree that the sending/receiving is able to be performed by transmitting infrared light or ultraviolet light.

According to the embodiments and the variant, a plurality (three in the illustrated example) of the second protective members 118 are provided. The number of second protective members 118 may be one. However, when a plurality of the second protective members 118 are provided, shocks acting on the electronic device are distributed among the second protective members 118. Thus, the electronic device 112 may be more effectively protected from the shocks from outside. In the structure in which the plurality of second protective members 118 are provided, the spaces between the second protective members 118 may be set so as not to block the curving in consideration of the shape of the electronic device 112 when the electronic device 112 is curved.

According to the embodiments and the variant, the rigidity of the first protective member 116 and the second protective members 118 may be set by the elastic modulus. For example, the elastic modulus of the first protective member 116 may be set to be a value between 50 kPa to 100 MPa. When the elastic modulus of the first protective member 116 is set to 50 kPa or larger, the first protective member 116 is elastically deformed by shocks from outside and may effectively absorb the shocks. When the elastic modulus of the first protective member 116 is set to 100 MPa or smaller, acting of excessive resistance on the curving of the electronic device 112 may be suppressed.

The elastic modulus of the second protective members 118 may be set to a value between 1 to 220 GPa. When the elastic modulus of the second protective members 118 is set to 1 GPa or larger, the second protective members 118 support shocks from outside and may effectively absorb the shocks by deformation of the second protective members 118 themselves. When the elastic modulus of the second protective members 118 is set to 220 GPa or smaller, the shape of the second protective members 118 may be stably maintained even when the electronic device 112 is curved.

Examples of the electronic device 112 of the present application include, for example, as described above, a device that includes an antenna therein so as to send and receive radio waves to and from the outside. The electronic device 112 may be a device that includes a light emitting element and a light receiving element therein so as to send and receive light. The electronic device 112 may be a device that includes a light emitting element and a display so as to allow surrounding operators to visually recognize the location and the state of the electronic device 112 by light emission or a display in a screen.

Although the embodiments of the technique disclosed herein have been described, the technique disclosed herein is not limited to the above description. Of course, in addition to the above description, the technique disclosed herein is able to be varied in a variety of manners and embodied without departing from the gist thereof.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electronic device comprising:
an electronic component;
a first protective member disposed so as to face one surface of the electronic component, the first protective member configured to be deformed by a shock from outside of the electronic component so as to relieve the shock; and
at least one second protective member disposed so as to face a surface of the first protective member opposite the electronic component, the at least one second protective member being harder than the first protective member, the at least one second protective member having a rod shape.

2. The electronic device according to claim 1, wherein
the electronic component includes:
a mounting surface to be brought into contact with a mounting target so as to allow mounting of the electronic component to the mounting target, and
a protected surface opposite the mounting surface, and
wherein the first protective member faces the protected surface.

3. The electronic device according to claim 2, wherein
the first protective member has a plate shape.

4. The electronic device according to claim 3, wherein
the first protective member is in surface contact with the protected surface.

5. The electronic device according to claim 2, wherein
the electronic component includes
a thin plate portion having the mounting surface, and
a thick plate portion that has a larger thickness than a thickness of the thin plate portion and that is fixed to the thin plate portion, and
wherein the first protective member is in contact with the thin plate portion and the thick plate portion.

6. The electronic device according to claim 2, wherein
a gap is formed between the first protective member and the at least one second protective member.

7. The electronic device according to claim 2, wherein
the at least one second protective member is in contact with the first protective member.

8. The electronic device according to claim 2, wherein
the at least one second protective member is in contact with the mounting target.

9. The electronic device according to claim 2, wherein
the at least one second protective member is spaced from the mounting target.

10. The electronic device according to claim 1, wherein
a longitudinal direction of the at least one second protective member is perpendicular to a longitudinal direction of the electronic component in plan view of the electronic component.

11. The electronic device according to claim 1, wherein
the at least one second protective member includes a plurality of the second protective members, and wherein
the plurality of second protective members are space from one another in a longitudinal direction of the electronic device.

12. The electronic device according to claim 1, wherein
the first protective member is transparent.
